(19) United States
(12) Patent Application Publication
(10) Pub. No.: US 2026/0223545 A1
(43) Pub. Date: Jul. 30, 2026

(54) DISPLAY PANEL, SPLICED SCREEN AND DISPLAY APPARATUS

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Yunpeng ZHANG, Beijing (CN); Xiangfei HE, Beijing (CN); Jingli YANG, Beijing (CN)

(21) Appl. No.: 19/146,950

(22) PCT Filed: Jun. 4, 2024
(86) PCT No.: PCT/CN2024/097155

§ 371 Date: Jul. 10, 2025

(30) Foreign Application Priority Data
Jun. 12, 2023 (CN) 202310696166.0

(51) Int. Cl. H10K 59/122; H10K 59/80

(52) U.S. Cl. CPC H10K 59/122; H10K 59/8792

(57) ABSTRACT

A display panel, a spliced screen and a display apparatus are provided. The display panel includes a display region (AA) and a border region (NA). The display region (AA) includes a first display region (AA1) adjacent to the border region (NA) and a second display region (AA2) on a side of the first display region (AA1) distal to the border region (NA); and a light transmission area of the first display region (AA1) per unit area is greater than a light transmission area of the second display region (AA2) per unit area.

### TECHNICAL FIELD

The present disclosure relates to the field of display technology, in particular to a display panel, a spliced screen and a display apparatus.

### BACKGROUND

With the development of electronic display products, consumers have higher and higher requirements for a screen-to-body ratio of a display screen, and nowadays, a display panel is technically limited, a non-display border region is still formed in an edge region of the display panel, and the visual effect still needs to be improved. On one hand, for a single independent display screen, the screen-to-body ratio of the display screen may be reduced due to the existence of the border region, so that the visual effect is still limited, and the user experience is influenced to a certain extent. On the other hand, with the development of industries such as outdoor advertising and indoor education, large-size screen display becomes an important branch of the display industry.

### SUMMARY

The present disclosure provides a display panel, a spliced screen and a display apparatus.

According to a first aspect of embodiments of the present disclosure, there is provided a display panel including a display region and a border region, wherein the display region includes a first display region adjacent to the border region, and a second display region on a side of the first display region distal to the border region; and a light transmission area of the first display region per unit area is greater than a light transmission area of the second display region per unit area.

In one embodiment, the display panel includes: a substrate; a pixel definition layer on one side of the substrate, and including a plurality of pixel openings and a plurality of pixel definition units; a plurality of light emitting units respectively in the plurality of pixel openings; and a color filter layer on a side of the pixel definition layer distal to the substrate, and including: a black matrix corresponding to the plurality of pixel definition units; and a plurality of filtering units respectively corresponding to the plurality of light emitting units; wherein the plurality of filtering units are in a filtering region, the filtering region includes a first filtering region in the first display region and a second filtering region in the second display region, and a light transmission area of the first filtering region is greater than a light transmission area of the second filtering region.

In one embodiment, the display panel further includes: a filling layer on a side of the color filter layer distal to the pixel definition layer, wherein at least part of the filling layer is in the first filtering region, and the plurality of filtering units are in the second filtering region.

In one embodiment, the plurality of filtering units include a first filtering unit in the first filtering region and a second filtering unit in the second filtering region, wherein a size of the first filtering unit in a direction perpendicular to the display panel is smaller than a size of the second filtering unit in the direction perpendicular to the display panel.

In one embodiment, the plurality of filtering units include a first filtering unit in the first filtering region and a second filtering unit in the second filtering region, wherein an area of a side of the first filtering unit proximal to the pixel definition layer is greater than an area of a side of the second filtering unit proximal to the pixel definition layer.

In one embodiment, the black matrix includes a first black matrix in the first display region and a second black matrix in the second display region, wherein an area of a side of the first black matrix proximal to the pixel definition layer is smaller than an area of a side of the second black matrix proximal to the pixel definition layer.

In one embodiment, the display panel further includes: a driving circuit layer in the display region, wherein the driving circuit layer is on a side of the substrate proximal to the pixel definition layer and is electrically connected to the plurality of light emitting units.

In one embodiment, the driving circuit layer includes a plurality of pixel driving circuits, wherein the plurality of pixel driving circuits are electrically connected to the plurality of light emitting units in one-to-one correspondence.

In one embodiment, the driving circuit layer includes a plurality of pixel driving circuits, wherein the plurality of pixel driving circuits are electrically connected to the plurality of light emitting units in one-to-many correspondence.

In one embodiment, the driving circuit layer includes a plurality of pixel driving circuits, wherein the plurality of pixel driving circuits are electrically connected to the plurality of light emitting units in many-to-one correspondence.

In one embodiment, the display panel includes, in the border region, an edge light emitting material definition region, in which a plurality of definition regions and a plurality of definition grooves are formed, in the pixel definition layer; and an edge light emitting material unit within the definition grooves.

In one embodiment, a distance from a light emitting unit in the border region to a light emitting unit, which is adjacent to the light emitting unit in the border region, in the first display region is equal to a distance between two adjacent light emitting units in the first display region.

In one embodiment, the plurality of light emitting units include a plurality of light emitting sub-units, and an arrangement of the light emitting sub-units in the first display region and an arrangement of the light emitting sub-units in the second display region are the same.

In one embodiment, the display panel includes V-shaped grooves and isolation pillars alternately arranged in the border region, and a depth of each V-shaped groove is greater than a height of each isolation pillar.

In one embodiment, the display panel includes a dam in the border region, and wherein a distance from a V-shaped groove, closest to the dam, to the dam is smaller than a distance from an isolation pillar, closest to the dam, to the dam on a side of the dam proximal to the display region.

In one embodiment, the filling layer and the black matrix both extend to and stop at a side of the dam proximal to the display region, and are directly in contact with the dam.

In one embodiment, in the border region, an orthographic projection of the black matrix on the substrate at least partially overlaps with orthographic projections of the V-shaped grooves and the isolation pillars on the substrate.

In one embodiment, a length of the black matrix in the border region is greater than a length of the black matrix in each of the first display region and the second display region.

According to a second aspect of the embodiments of the present disclosure, there is provided a spliced screen, including a plurality of the display panels provided in the foregoing embodiments, where the border regions of the plurality of display panels are spliced with each other.

According to a third aspect of embodiments of the present disclosure, there is provided a display apparatus, including the display panel or the spliced screen provided in the foregoing embodiments.

Additional aspects and advantages of the present disclosure will be set forth in part in the following description and will be obvious from the description, or may be learned by practice of the present disclosure.

### BRIEF DESCRIPTION OF FIGURES

The accompanying drawings, which are incorporated in this specification and constitute a part of this specification, illustrate embodiments consistent with the present disclosure and serve to explain the principles of the present disclosure together with the description.

FIG. 1 is a schematic diagram of an arrangement of light emitting units of a spliced screen in the related art.

FIG. 2 is a schematic diagram of an arrangement of light emitting units of a display panel according to an embodiment of the present disclosure.

FIG. 3 is a cross-sectional view of layers of a display panel taken along a dashed line AA′ in FIG. 2 according to an embodiment of the present disclosure.

FIG. 4 is another cross-sectional view of layers of a display panel taken along a dashed line AA′ in FIG. 2 according to an embodiment of the present disclosure.

FIG. 5 is another cross-sectional view of layers of a display panel taken along a dashed line AA′ in FIG. 2 according to an embodiment of the present disclosure.

FIG. 6 is another cross-sectional view of layers of a display panel taken along a dashed line AA′ in FIG. 2 according to an embodiment of the present disclosure.

FIG. 7 is a schematic diagram of layers of a display panel according to an embodiment of the present disclosure.

In the drawings:
100—Light emitting unit; 101—First light emitting sub-unit; 102—Second light emitting sub-unit; 103—Third light emitting sub-unit; AA—Display region; AA1—First display region; AA2—Second display region; NA—Border region; 110—Substrate; 111—First barrier layer; 112—Second barrier layer; 200—Driving circuit layer; 201—Pixel driving circuit; 211—First source electrode; 212—Second source electrode; 213—First drain electrode; 214—Second drain electrode; 215—First gate electrode; 216—Active layer; 217—Second gate electrode; 221—First gate insulation layer; 222—Second gate insulation layer; 230—Interlayer dielectric layer; 240—Passivation layer; 251—First planarization layer; 252—Second planarization layer; 310—First electrode; 320—Pixel definition layer; 321—Pixel opening; 322—Pixel definition unit; 330—Second electrode; 400—Encapsulation layer; 500—Color filter layer; 510—Black matrix; 511—First black matrix; 512—Second black matrix; 520—Filtering unit; 521—First filtering unit; 522—Second filtering unit; 600—Dam; 700—Filling layer; 1001—V-shaped groove; 1002—Isolation pillar.

### DETAILED DESCRIPTION

The exemplary embodiments will be described in detail here, and the examples are illustrated in the accompanying drawings. The following description refers to the accompanying drawings in which the same reference numbers in different drawings represent the same or similar elements unless otherwise indicated. The embodiments described in the exemplary embodiments below do not represent all embodiments consistent with the present disclosure. Rather, they are merely examples of apparatus and methods consistent with certain aspects of the present disclosure, as detailed in the appended claims.

The terminology used herein is for the purpose of describing particular embodiments only and is not intended to be limiting of the present disclosure. As used in the present disclosure and the appended claims, the singular forms “a”, “an”, and “the” are intended to include the plural forms as well, unless the context clearly indicates otherwise. It should also be understood that the term “and/or” as used herein refers to and encompasses any and all possible combinations of one or more of the associated listed items.

With the development of the times, consumers are pursuing higher and higher display screens of electronic display products. The screen-to-body ratio of the single display screen cannot reach 100%. A border region and spliced seams of a spliced screen may cause displayed pictures to have a strong splitting feeling in visual effect. Therefore, an organic light emitting diode (OLED) may become an important development direction in the field.

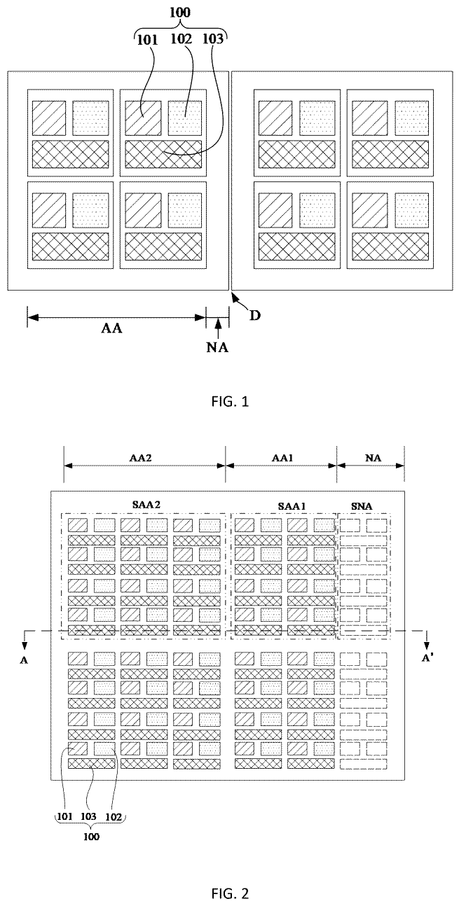

The spliced screen is formed by splicing a plurality of display screens independent from each other, and a spliced seam D (shown in FIG. 1) exists between the two screens. Due to the existence of the spliced seam, a pixel pitch at a splicing position is inconsistent with that at a middle position, and the pixel pitch at the spliced seam is greater, so that the displayed pictures have the splitting feeling. A size of the spliced seam directly affects the display effect. For example, an LCD (liquid crystal display) is generally narrow but has a great spliced seam, the spliced seam cannot be used to display, and therefore, the display splitting feeling is caused. Therefore, the size of the spliced seam needs to be reduced. In order to reduce the size of the spliced seam, VSS ground lines may be distributed in the middle of an AA (active area) by adopting an auxiliary cathode technology in the product, thereby eliminating the influence of the VSS ground lines on the border. However, an encapsulation border cannot be eliminated and can only be reduced in the existing OLED technology, so that the spliced seam always exists. However, the OLED has a larger pixel structure, and in the limitation of a design with a great aperture ratio and a fine mask of the OLED, the border region at the splicing position cannot emit light and has a greater space, which cannot improve the display effect.

The present disclosure provides a display panel, a spliced screen and a display apparatus and aims at solving the above technical problems in the related art.

The display panel, the spliced screen, and the display apparatus in the embodiments of the present disclosure are described in detail below with reference to the drawings. The features of the embodiments described below may complement each other or be combined with each other without conflict.

The embodiment of the present disclosure provides a display panel, as shown in FIG. 2, including a display region AA and a border region NA at least partially surrounding the display region AA. The display region AA includes a first display region AA1 adjacent to the border region NA, and a second display region AA2 on a side of the first display region AA1 distal to the border region NA. A light transmission area per unit area of the first display region AA1 is greater than that of the second display region AA2.

In this embodiment, the light transmission area per unit area of the first display region AA1 of the display panel is greater than that of the second display region AA2. For example, in one aspect, the first display region AA1 and the border region NA adjacent to each other may be regarded as a whole as an “edge region”, and the border region NA may be regarded as a non-light emitting region within the “edge region”. As shown in FIG. 2, when the light emitting units are arranged in an array on the display panel, a light emitting area per unit area of the edge region (including the first display region AA1 and the border region NA) is smaller than a light emitting area per unit area of the second display region AA2, and the non-light emitting region of the edge region may be used to form the border region NA. For example: as shown in FIG. 2, taking 3×4 light emitting units 100 are arranged in per unit area as an example (three light emitting units 100 in each row along a horizontal direction, and four light emitting units 100 in each column along a vertical direction), the edge region (the first display region AA1 and the border region NA) is in the region of 3×4 light emitting units 100 per unit area, that is, the edge region is in the region including a SAA1 region (each row of 2 light emitting units 100 in the horizontal direction and each column of 4 light emitting units 100 in the vertical direction, the 2×4 light emitting units 100 may be used as the light emitting area) and a SNA region (each row of 1 light emitting unit 100 in the horizontal direction and each column of 4 light emitting units 100 in the vertical direction, the 1×4 light emitting units are not used as the light emitting area), and the light emitting area thereof has (corresponds to) the 2×4 light emitting units 100 therein; the second display region AA2 is in the region of 3×4 light emitting units 100 per unit area, and the light emitting area thereof includes a SAA2 region having 3×4 light emitting units 100 therein (each row of 3 light emitting units 100 in a horizontal direction, each column of 4 light emitting units 100 in a vertical direction, and the 3×4 light emitting units 100 may be used as the light emitting area).

For example, the light emitting area may refer to an area of an orthographic projection of a light emitting unit 100 or a light emitting sub-unit on the substrate, and the light transmission area may refer to an area of an orthographic projection of a portion for controlling the light emitting (such as a filtering region) of the light emitting unit 100 or the light emitting sub-unit on the substrate. The unit area may include one or more light emitting units 100 or light emitting sub-units.

In the present disclosure, the border region NA is formed by sacrificing light emitting regions of the light emitting units adjacent to the border in the related art, which can increase the screen-to-body ratio of the single display screen or improve the splitting feeling of the displayed pictures due to the existence of the spliced seam of the spliced screen. Meanwhile, when the light emitting area per unit area of the edge region is smaller than that of the second display region AA2, the life spans of the light emitting units in the edge region per unit area is different from the life spans of the light emitting units in the second display region AA2, so that the life spans of the light emitting units in the regions of the display screen may be non-uniform, and the screen display and the user experience may be affected. Therefore, the light transmission area of the first display region AA1 is increased, so that the light transmission area of the first display region AA1 is greater than that of the second display region AA2, and the light emitting intensity of the light emitting units in the first display region AA1 is adjusted to be smaller than that in the second display region AA2 under the operating condition, so that the light emitting life spans of the light emitting units in the first display region AA1 can be prolonged in a case that the display brightness of the light emitting units is consistent, the life spans of the light emitting units in the edge region per unit area are the same as those of the light emitting units in the second display region AA2, the display quality of the display panel can be ensured, the influence of the border region NA on the display effect of the display panel can be weakened visually, the screen-to-body ratio regarding the visual effect can be increased, the splitting feeling of the displayed pictures of the spliced screen can be weakened, and the user experience can be improved.

In some embodiments, a size of each light emitting unit 100 may be further reduced, so that the number of the light emitting units 100 per unit area is increased, the pixel density of the display panel is further improved, and the existence of the border region NA and the spliced seam is weakened, thereby optimizing the display effect and improving the user experience. For example, as shown in FIGS. 1 to 2, the display panel is further divided, so that a region where four light emitting units 100 are originally provided of the display panel has twelve light emitting units 100 therein.

In some embodiments, as shown in FIGS. 1 to 2, the display panel includes a plurality of light emitting units 100, each light emitting unit 100 includes a plurality of light emitting sub-units. For example, each light emitting unit 100 includes a first light emitting sub-unit 101, a second light emitting sub-unit 102, and a third light emitting sub-unit 103, wherein light emitting colors of the first light emitting sub-unit 101, the second light emitting sub-unit 102, and the third light emitting sub-unit 103 are different from each other. For example, the arrangement of the light emitting sub-units in this embodiment is Real RGB arrangement. The light emitting color of the first light emitting sub-unit 101 is red, the light emitting color of the second light emitting sub-unit 102 is green, and the light emitting color of the third light emitting sub-unit 103 is blue. A light emitting area of the blue sub-pixel is greater than that of the red/green sub-pixel, the light emitting life span of the blue sub-pixel is prolonged by increasing the light emitting area of the blue sub-pixel, and the uniformity of the display effect of the display panel is improved.

It should be noted that the arrangement of the light emitting sub-units further includes, but is not limited to, Real RGB arrangement, pentile arrangement, diamond arrangement, or Delta arrangement.

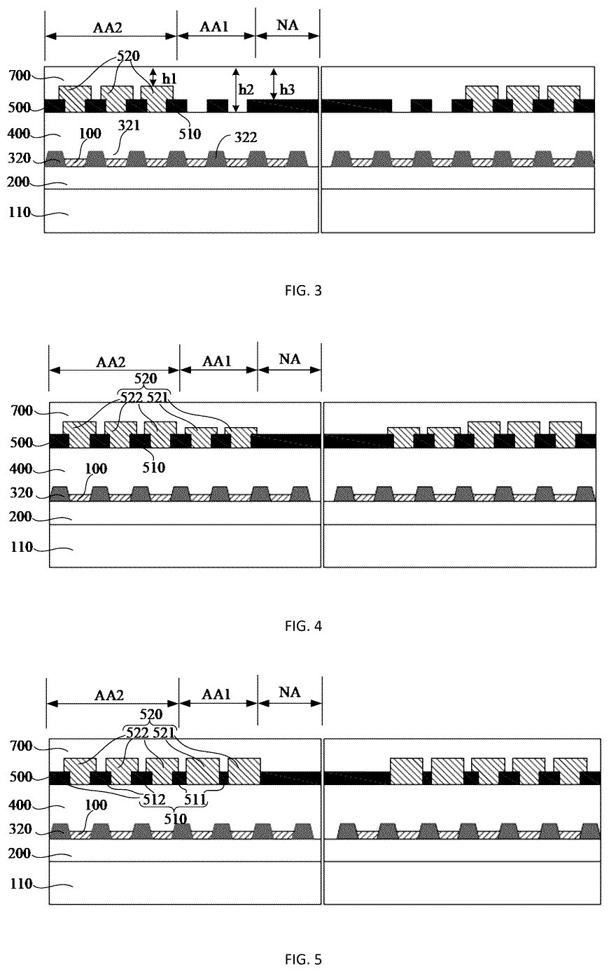

In some embodiments, as shown in FIGS. 3 to 5, the display panel includes: a substrate 110, a pixel definition layer 320, a plurality of light emitting units 100, and a color filter layer 500. The pixel definition layer 320 is disposed on one side of the substrate 110, and includes a plurality of pixel openings 321 and a plurality of pixel definition units 322. The plurality of light emitting units 100 are respectively located in the plurality of pixel openings 321. The color filter layer 500 is located on a side of the pixel definition layer 320 distal to the substrate 110, and includes a black matrix 510 disposed corresponding to the pixel definition units 322 and a plurality of filtering units 520 disposed corresponding to the plurality of light emitting units 100. The filtering unit 520 is located in a filtering region, the filtering region includes a first filtering region located in the first display region AA1 and a second filtering region located in the second display region AA2, and a light transmission area of the first filtering region is greater than a light transmission area of the second filtering region.

In this embodiment, the light transmission area of the first filtering region of the color filter layer 500 is greater than the light transmission area of the second filtering region. That is, the light transmittance of the first filtering region of the color filter layer 500 is greater than that of the second filtering region (the light transmittance may refer to a percentage of the light flux to the incident light flux. For example, the light transmittance may be a percentage of the light flux passing through the filtering region to the incident light flux incident on the filtering region in the light emitting unit 100. In some embodiments, for example, if the medium through which light passes is the same, the light transmittance=light transmission area/light emitting area.) It can be realized that the light transmitted through the light emitting region corresponding to the first filtering region is more than that transmitted through the light emitting region corresponding to the second filtering region, and the light emitting intensity of the light emitting units 100 in the first display region AA1 may be weaker than that in the second display region AA2, and further, the light emitting life spans of the light emitting units 100 in the first display region AA1 may be prolonged, so that the uniformity of the light emitting life spans of the light emitting units 100 of the display panel is realized, the display quality of the display panel is improved, and the user experience is improved.

It should be noted that the pol-less technology (such as color filter on encapsulation (COE)) may be adopted in this embodiment, that is, after an AMOLED (an active-matrix organic light emitting diode) is encapsulated, a color filter (CF) is plated on a side of an encapsulation layer 400 distal to the substrate 110, where the color filter on each pixel corresponds to a color of the pixel, and any two adjacent color filters are separated from each other by a corresponding black matrix 510 (BM) by a gap. The color filter in the COE technology can solve the problems of light reflection and light transmission. The unnecessary portion of the incident light from the outside is absorbed by the black matrix 510, and the necessary portion of the incident light from the outside is reflected out through the color filter region. The color filter has high dominant wavelength transmittance for RGB, which is in a range from about 70% to 90%, and is much greater than that of a polarizer.

In some embodiments, each of the light emitting units 100 includes a red light emitting sub-unit, a blue light emitting sub-unit, and a green light emitting sub-unit. The color filter layer 500 also includes a red filtering region, a blue filtering region and a green filtering region in one-to-one correspondence with the light emitting sub-units of the light emitting units 100.

It is noted that the substrate 110 may be a rigid substrate or a flexible substrate, and the substrate 110 is made of an insulating material such as glass, quartz, and polymer resin. Further, the substrate 110 is made of CPI (colorless polyimide), PET (poly-ethylene terephthalate), or UTG (ultra thin glass).

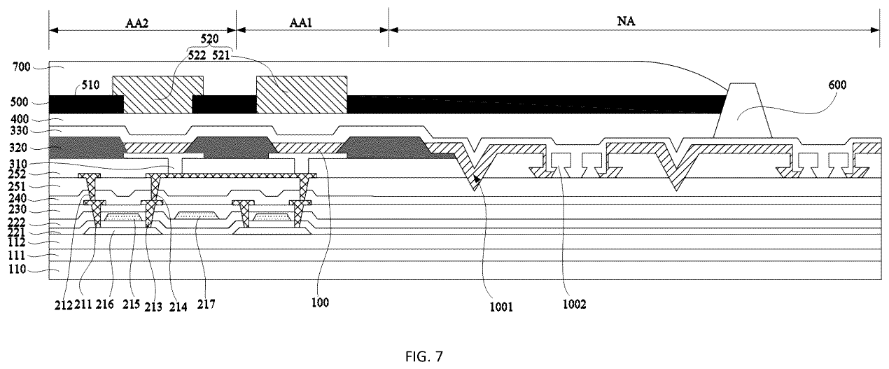

In some embodiments, as shown in FIG. 7, a first electrode 310 is provided on a side of the pixel definition layer 320 proximal to the substrate 110, and a second electrode 330 is provided on a side of the pixel definition layer 320 distal to the substrate 110. For example, the first electrode 310 is an anode, which may be made of ITO or IZO, and the second electrode 330 is a cathode, which may be made of Mg/Ag.

In some embodiments, as shown in FIGS. 3 to 5, the encapsulation layer 400 is disposed on a side of the color filter layer 500 proximal to the pixel definition layer 320, and includes at least one inorganic layer for preventing oxygen and water from penetrating into the light emitting units 100 in the pixel definition layer 320.

In some embodiments, as shown in FIG. 3, the display panel further includes a filling layer 700 in the first filtering region and on a side of the color filter layer 500 distal to the pixel definition layer 320. The filtering units 520 are located in the second filtering region. In this embodiment, the first display region AA1 is designed by omitting color filters (skip), that is, the filtering region of the first display region AA1 has no color filters therein (i.e., no filtering units 520) and still has the black matrix 510 therein as usual. After the color filter has been plated, the filling layer 700 is directly disposed on the color filter region (i.e., the filtering region) that is hollowed out, and the light transmittance of the filling layer 700 may be made greater than that of the filtering unit 520. It can be realized that the light transmitted through the light emitting region corresponding to the first filtering region is more than that transmitted through the light emitting region corresponding to the second filtering region, and the light emitting intensity of the light emitting units 100 in the first display region AA1 may be weaker than that in the second display region AA2, and further, the light emitting life spans of the light emitting units 100 in the first display region AA1 may be prolonged, so that the uniformity of the light emitting life spans of the light emitting units 100 of the display panel is realized, the display quality of the display panel is improved, and the user experience is improved.

In some embodiments, as shown in FIG. 3, a thickness h2 of a portion of the filling layer 700 in the first display region AA1 is greater than a thickness h3 of a portion of the filling layer 700 in the border region NA and greater than a thickness h1 of a portion of the filling layer 700 in the second display region AA2. With such a design, it is advantageous to balance the transmittance of light in the first display region AA1 and the transmittance of light in the first display region AA2.

In some embodiments, the filling layer 700 is made of an organic insulating material. The organic insulating material may include an imide polymer, a commercial polymer (such as polymethyl methacrylate (PMMA) or polystyrene (PS)), a polymer derivative having a phenolic group, an acryl polymer, an aryl ether polymer, an amide polymer, a fluorine polymer, a p-xylene polymer, or a vinyl alcohol polymer.

In some embodiments, as shown in FIG. 4, the plurality of filtering units 520 includes first filtering units 521 located in the first filtering region and second filtering units 522 located in the second filtering region, and a size of each first filtering unit 521 in a direction perpendicular to the display panel is smaller than a size of each second filtering unit 522 in the direction perpendicular to the display panel.

In this embodiment, when the light transmittance of the first filtering unit 521 per unit size (e.g., per unit area) is the same as the light transmittance of the second filtering unit 522 per unit size, a thickness of the first filtering unit 521 is smaller than that of the second filtering unit 522, so that the light transmittance of the first filtering unit 521 may be greater than that of the second filtering unit 522. Further, the light emitting intensity of the light emitting units 100 in the first display region AA1 is reduced by adjusting a driving current of the corresponding light emitting unit 100, so that the light emitting life spans of the light emitting units 100 in the first display region AA1 is prolonged, the uniformity of the light emitting life spans of the light emitting units 100 of the display panel is realized, the display quality of the display panel is improved, and the user experience is improved.

It should be noted that the light transmittance of the first filtering unit 521 per unit size may be the same as or different from the light transmittance of the second filtering unit 522 per unit size, and when the light transmittance of the first filtering unit 521 per unit size is smaller than the light transmittance of the second filtering unit 522 per unit size, it is necessary to ensure that the thickness of the first filtering unit 521 is much smaller than the thickness of the second filtering unit 522.

Furthermore, a difference value between the thickness of the first filtering unit 521 and the thickness of the second filtering unit 522 is related to a ratio of the light emitting area of the first display region AA1 per unit area to the light emitting area of the second display region AA2 per unit area, and can be flexibly set by one of ordinary skill in the art according to actual situations. For example, the difference value between the thickness of the first filtering unit 521 and the thickness of the second filtering unit 522 is p1, and the ratio of the light emitting area of the edge region (including the first display region AA1 and the border region NA) per unit area to the light emitting area of the second display region AA2 per unit area is S1, where K=p1/S1, and K is in a range from 0.95 to 1.05. The brightness difference between the first display region AA1 and the second display region AA2 can be ensured to be small, and a better display effect can be ensured.

In some embodiments, as shown in FIG. 5, the filtering units 520 include a first filtering unit 521 located in the first filtering region and a second filtering unit 522 located in the second filtering region, and an area of a portion of the first filtering unit 521 proximal to the pixel definition layer 320 is greater than an area of a portion of the second filtering unit 522 proximal to the pixel definition layer 320.

In this embodiment, the area of the portion of the first filtering unit 521 proximal to the pixel definition layer 320 is relatively great, so that when external light is incident on the surface of the light emitting units 100, the amount of reflected light is increased, thereby increasing the light transmittance of the first filtering unit 521, further by flexibly adjusting the light emitting intensity of the light emitting units 100 in the first display region AA1, thereby prolonging the life spans of the light emitting units, compensating the reduced light emitting area caused by the border region NA (non-light emitting region) in the edge region, increasing the uniformity of the light emitting life spans of the light emitting units 100 of the display panel, increasing the display quality of the display panel, and improving the user experience.

It should be noted that when the area of the portion of the first filtering unit 521 proximal to the pixel definition layer 320 is increased, an area of the corresponding black matrix 510 adjacent to the portion of the first filtering unit 521 proximal to the pixel definition layer 320 may be increased, decreased or unchanged, which may be flexibly selected according to the actual situation in the field. When the area of the black matrix 510 is increased, it is necessary to ensure that the increased light transmittance of the filtering unit 520 with an increased area is greater than the increased light absorptivity of the black matrix 510 with an increased area.

In some embodiments, as shown in FIG. 5, the black matrix 510 includes a first black matrix 511 located in the first display region AA1 and a second black matrix 512 located in the second display region AA2, and an area of a side of the first black matrix 511 proximal to the pixel definition layer 320 is smaller than an area of a side of the second black matrix 512 proximal to the pixel definition layer 320.

In this embodiment, the area of the side of the black matrix 510 proximal to the pixel definition layer 320 is reduced, thereby reducing the light absorptivity of the black matrix 510, indirectly increasing the light transmittance of the first filtering region, further flexibly adjusting the light emitting intensity of the light emitting units 100 in the first display region AA1, prolonging the life spans of the light emitting units, compensating the reduced light emitting area caused by the edge region, increasing the uniformity of the light emitting life spans of the light emitting units 100 of the display panel, and optimizing the application of the display panel and the spliced screen and the like in the field of display technology.

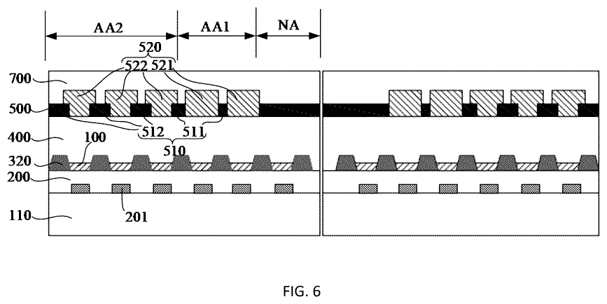

In some embodiments, as shown in FIGS. 3 to 6, the display region AA further includes a driving circuit layer 200. The driving circuit layer 200 is disposed on a side of the substrate 110 proximal to the pixel definition layer 320, and is electrically connected to the light emitting units 100.

In some embodiments, the driving circuit layer 200 includes a plurality of pixel driving circuits 201 electrically connected to the light emitting units 100 in one-to-one correspondence.

For example, as shown in FIG. 2, in the present embodiment, a region where one pixel unit is located is set to include 12 small pixel units which are respectively driven by 12 pixel driving circuits, and the same or single data signal is written into the 12 small pixel units.

In some embodiments, the driving circuit layer 200 includes a plurality of pixel driving circuits 201 electrically connected to the light emitting units 100 in one-to-many correspondence.

For example, in this embodiment, a region where one pixel unit is located is set to include 12 small pixel units which may be driven by the same pixel circuit to implement parallel connection therebetween.

In some embodiments, the driving circuit layer 200 includes a plurality of pixel driving circuits 201 electrically connected to the light emitting units 100 in many-to-one correspondence.

In some embodiments, as shown in FIG. 7, the display panel further includes a first barrier layer 111 (barrier 1) and a second barrier layer 112 (barrier 2) sequentially stacked on the substrate 110, and the driving circuit layer 200 includes a thin film transistor including a first source electrode 211, a second source electrode 212, an active layer 216, a first drain electrode 213, and a second drain electrode 214 sequentially connected, and a first gate electrode 215 and a second gate electrode 217 on a side of the active layer 216 distal to the substrate 110. The driving circuit layer 200 further includes a first gate insulating layer 221, a second gate insulating layer 222, an interlayer dielectric layer 230 (ILD), a passivation layer 240 (PVX), a first planarization layer 251 (PLN1), and a second planarization layer 252 (PLN2) sequentially stacked on the substrate 110.

In some embodiments, as shown in FIG. 7, the border region NA includes: an edge light emitting material definition region and an edge light emitting material unit. The edge light emitting material definition region is located in the pixel definition layer 320, and has a plurality of definition regions and a definition groove formed therein. The edge light emitting material unit is located within the definition groove.

In the foregoing embodiment, the border region NA is formed by sacrificing the space where the pixels at edges are located, and the display effect is improved by reducing the size of the pixels, which may have a certain effect on the manufacturing process. Since the mask in the related art usually is a mold with a fixed shape to form a plurality of pixel units arranged in an array, in order to save the manufacturing cost of the mask, simplify the model of the mask, and simplify the manufacturing process, the process of forming the “pixel definition layer 320” (i.e., the edge light emitting material definition region) in the border region NA is still remained in this embodiment, but other layers in the border region NA are still consistent with those in the border region NA in the related art, and the edge light emitting material units in the edge light emitting material definition region of the border region NA are not additionally connected to a driving circuit, so as to ensure that the border region NA has a sufficient space to form a related encapsulation structure. The definition groove in the embodiment can prevent the light emitting materials inside and outside the encapsulation border from being connected together, so as to realize the effect of isolating water vapor. For example, the definition region has a plurality of isolation pillars 1002 formed therein for isolating the light emitting material.

In some embodiments, as shown in FIG. 7, the second planarization layer 252 located in the border region NA has a plurality of V-shaped grooves 1001 formed therein, to prevent portions of the second planarization layer 252 from being connected to each other, so as to avoid moisture erosion. Meanwhile, a dam 600 is formed in the border region NA in this embodiment to block the organic material in the planarization layer from flowing or leaking to the outside. Compared with the prior art that two dams (DAM) are usually adopted to effectively prevent the organic material from being exposed or leaking to the outside of the display apparatus, in the embodiment, the V-shaped grooves 1001 can primarily block the flow of the organic material and reduce a height of an organic material layer, and further, one dam 600 can effectively prevent the organic material from being exposed or leaking to the outside of the display apparatus, so that the manufacturing process is simplified, and the encapsulation cost is saved. Note that the dam 600 may be formed of an organic film such as an acrylic resin, an epoxy resin, a phenol resin, a polyamide resin, or a polyimide resin.

In some embodiments, as shown in FIG. 7, in the border region NA, the V-shaped grooves 1001 and the isolation pillars 1002 are alternately arranged, and a depth of the V-shaped groove 1001 is greater than a height of the isolation pillar 1002 so as to block the organic material in the second planarization layer 252 from flowing or leaking.

In some embodiments, as shown in FIG. 7, in the border region NA, the V-shaped groove 1001 and the isolation pillar 1002 may be formed on each of two sides of the dam 600. On a side of the dam 600 proximal to the display region AA, a distance from a first V-shaped groove 1001 closest to the dam 600 to the dam 600 is smaller than a distance from a first isolation pillar 1002 closest to the dam 600 to the dam 600. For example, a distance from a center line of the first V-shaped groove 1001 to a center line of the dam 600 is smaller than a distance from a center line of the first isolation pillar 1002 to the center line of the dam 600, thereby advantageously preventing the organic material from flowing or leaking to the display region AA through the V-shaped groove 1001.

In some embodiments, as shown in FIG. 7, in the border region NA, the light emitting material of the light emitting units 100 and the second electrode 330 may be filled into the V-shaped groove 1001, or into a gap between the V-shaped groove 1001 and the isolation pillar 1002.

In some embodiments, as shown in FIG. 7, in the border region NA, an orthographic projection of each of the filling layer 700, the black matrix 510 and the encapsulation layer 400 on the substrate 110 may at least partially overlap with orthographic projections of the V-shaped grooves 1001 and the isolation pillars 1002 on the substrate 110, which is beneficial to achieving the planarization of the border region NA. The filling layer 700 and the black matrix 510 both extend to and stop at a side of the dam 600 proximal to the display region AA1, and are directly in contact with the dam 600, which is beneficial to forming a tight encapsulation structure.

In some embodiments, as shown in FIG. 7, a length of the black matrix 510 in the border region NA is greater than a length of the black matrix in each of the first display region AA1 and the second display region AA2. For example, the length of the black matrix 510 in the border region NA is 3 to 5 times that of the black matrix in each of the first display region AA1 and the second display region AA2, so that light in the border region NA can be blocked, and the border region NA can be flattened. In some embodiments, a distance between the light emitting unit 100 in the border region NA and the light emitting unit 100 in the first display region AA1 adjacent to the light emitting unit 100 in the border region NA is equal to a distance between any two adjacent light emitting units 100 in the first display region AA1. In some embodiments, a distance from the center of the light emitting unit 100 in the border region NA to the center of the light emitting unit 100, adjacent to the light emitting unit 100 in the border region NA, in the first display region AA1 is equal to a distance between the centers of two adjacent light emitting units 100 in the first display region AA1.

With reference to the foregoing embodiments, the border region NA is provided with the edge light emitting material unit, which is equivalent to the “pixel” existing in the border region, and when the original large-sized pixel is divided into small-sized pixels, the distance from the center of the light emitting unit 100 in the border region NA to the center of the light emitting unit 100, adjacent to the light emitting unit 100 in the border region NA, in the first display region AA1 is equal to a distance between the centers of two adjacent light emitting units 100 in the first display region AA1. In this case, a region where the pixels are located of the edge region is formed as the border region NA when a plurality of display panels form the spliced screen, and a design in which the pixels of the plurality of display panels are separated from each other by an equal pitch can be realized, so that the display splitting feeling caused by the low screen-to-body ratio for the spliced screen in the related art can be weakened.

In some embodiments, the light emitting units 100 includes a plurality of light emitting sub-units, and the light emitting sub-units in the first display region AA1 and the light emitting sub-units in the second display region AA2 are arranged in the same manner. Regular arrangement of pixels can be realized to make full use of the space.

Based on the same inventive concept, the embodiment of the present disclosure provides a spliced screen, including a plurality of the display panels provided in the foregoing embodiments, and the border regions NA of the plurality of display panels are spliced with each other. Therefore, the spliced screen has all the characteristics and advantages of the display panel, which is not described in detail herein.

Based on the same inventive concept, the embodiment of the present disclosure provides a display apparatus, including the display panel or the spliced screen provided in the foregoing embodiments. Therefore, the display apparatus has all the characteristics and advantages of the display panel or the spliced screen, which is not described in detail herein.

It should be noted that the display apparatus may be any device that displays text or images, whether in motion (e.g., video) or stationary (e.g., still images). More particularly, it is contemplated that the embodiments may be implemented in or associated with a variety of electronic devices such as, but not limited to, a mobile telephone, a wireless device, a personal data assistant (PDA), a hand-held or portable computer, a GPS receiver/navigator, a camera, an MP4 video player, a camcorder, a game console, a wrist watch, a clock, a calculator, a television monitor, a flat panel display, a computer monitor, an auto display (e.g., an odometer display), a navigator, a cockpit controller and/or display, a camera view display (e.g., a display of a rear view camera in a vehicle), an electronic photograph, an electronic billboard or indicator, a projector, an architectural structure, a packaging, or an aesthetic structure (e.g., a displays of an image for a piece of jewelry), or the like.

The above embodiments of the present disclosure may complement each other without conflict.

It is noted that a size of a layer or a region may be exaggerated for clarity in the drawings. Also, it will be understood that when an element or layer is referred to as being “on” another element or layer, the element or layer may be directly located on the other element or intervening layers may also be present therebetween. In addition, it will be understood that when an element or layer is referred to as being “under” another element or layer, the element or layer may be directly located under the other element or intervening layers or elements may be present therebetween. In addition, it will also be understood that when a layer or element is referred to as being “between” two layers or elements, the element or layer may be the only layer between the two layers or elements, or intervening layers or elements may be present therebetween. Like reference numerals refer to like elements throughout.

The terms “middle”, “upper”, “lower”, “front”, “rear”, “left,” “right,” “vertical”, “horizontal”, “top”, “bottom”, “inner”, “outer”, and the like indicate the orientation or positional relationship based on those shown in the drawings for ease of description and simplicity of description, but do not indicate or imply that the device or element referred to must have a specific orientation, be constructed and operated in a specific orientation, thus, which should not be construed as limiting the present disclosure.

The terms “first” and “second” are used for descriptive purposes only and are not to be construed as indicating or implying relative importance or to implicitly indicate the number of technical features indicated. Thus, a feature defined with “first” or “second” may explicitly or implicitly include one or more of the features. In the description of the present disclosure, the meaning of “a plurality” is two or more unless otherwise specified.

Other embodiments of the present disclosure will be apparent to one of ordinary skill in the art from consideration of the specification and practice of the content disclosed herein. The present disclosure is intended to cover any variations, uses, or adaptations of the present disclosure, and these variations, uses, or adaptations follow the general principle of the present disclosure and include the common general knowledge or the general technical means in the art, which is not disclosed in the present disclosure. The specification and embodiments are considered as exemplary only, with a true scope and spirit of the present disclosure being indicated by the claims.

It will be understood that the present disclosure is not limited to the precise arrangements that have been described above and shown in the drawings, and that various modifications and changes may be made without departing from the scope of the present disclosure. The scope of the present disclosure is limited only by the appended claims.

1. A display panel comprising a display region and a border region, wherein the display region comprises a first display region adjacent to the border region, and a second display region on a side of the first display region distal to the border region; and
a light transmission area of the first display region per unit area is greater than a light transmission area of the second display region per unit area.

2. The display panel according to claim 1, wherein the display panel comprises:
a substrate;
a pixel definition layer on one side of the substrate, and comprising a plurality of pixel openings and a plurality of pixel definition units;
a plurality of light emitting units respectively in the plurality of pixel openings; and
a color filter layer on a side of the pixel definition layer distal to the substrate, and comprising:
a black matrix corresponding to the plurality of pixel definition units; and
a plurality of filtering units respectively corresponding to the plurality of light emitting units; wherein the plurality of filtering units are in a filtering region comprising a first filtering region in the first display region and a second filtering region in the second display region, and a light transmission area of the first filtering region is greater than a light transmission area of the second filtering region.

3. The display panel according to claim 2, wherein the display panel further comprises:
a filling layer on a side of the color filter layer distal to the pixel definition layer, wherein at least part of the filling layer is in the first filtering region, and the plurality of filtering units are in the second filtering region.

4. The display panel according to claim 2, wherein
the plurality of filtering units comprise a first filtering unit in the first filtering region and a second filtering unit in the second filtering region, wherein a size of the first filtering unit in a direction perpendicular to the display panel is smaller than a size of the second filtering unit in the direction perpendicular to the display panel.

5. The display panel according to claim 2, wherein
the plurality of filtering units comprise a first filtering unit in the first filtering region and a second filtering unit in the second filtering region, wherein an area of a side of the first filtering unit proximal to the pixel definition layer is greater than an area of a side of the second filtering unit proximal to the pixel definition layer.

6. The display panel according to claim 2, wherein
the black matrix comprises a first black matrix in the first display region and a second black matrix in the second display region, wherein an area of a side of the first black matrix proximal to the pixel definition layer is smaller than an area of a side of the second black matrix proximal to the pixel definition layer.

7. The display panel according to claim 2, wherein the display panel further comprises:
a driving circuit layer in the display region, wherein the driving circuit layer is on a side of the substrate proximal to the pixel definition layer and is electrically connected to the plurality of light emitting units.

8. The display panel according to claim 7, wherein the driving circuit layer comprises a plurality of pixel driving circuits respectively electrically connected to the plurality of light emitting units in one-to-one correspondence.

9. The display panel according to claim 7, wherein the driving circuit layer comprises a plurality of pixel driving circuits electrically connected to the plurality of light emitting units in one-to-many correspondence.

10. The display panel according to claim 7, wherein the driving circuit layer comprises a plurality of pixel driving circuits electrically connected to the plurality of light emitting units in many-to-one correspondence.

11. The display panel according to claim 2, wherein the display panel comprises:
an edge light emitting material definition region, in which a plurality of definition regions and a plurality of definition grooves are formed, in the pixel definition layer in the border region; and
an edge light emitting material unit within the definition grooves in the border region.

12. The display panel according to claim 2, wherein a distance from a light emitting unit in the border region to a light emitting unit, which is adjacent to the light emitting unit in the border region, in the first display region is equal to a distance between two adjacent light emitting units in the first display region.

13. The display panel according to claim 2, wherein the plurality of light emitting units comprise a plurality of light emitting sub-units, and an arrangement of the light emitting sub-units in the first display region is the same as an arrangement of the light emitting sub-units in the second display region.

14. The display panel according to claim 2, wherein the display panel comprises V-shaped grooves and isolation pillars alternately arranged in the border region, and a depth of the V-shaped groove is greater than a height of the isolation pillar.

15. The display panel according to claim 14, wherein the display panel comprises a dam in the border region, and wherein a distance from a V-shaped groove, closest to the dam, to the dam is smaller than a distance from an isolation pillar, closest to the dam, to the dam on a side of the dam proximal to the display region.

16. The display panel according to claim 15, wherein the filling layer and the black matrix both extend to and stop at a side of the dam proximal to the display region, and are directly in contact with the dam.

17. The display panel according to claim 15, wherein in the border region, an orthographic projection of the black matrix on the substrate at least partially overlaps with orthographic projections of the V-shaped grooves and the isolation pillars on the substrate.

18. The display panel according to claim 2, wherein a length of the black matrix in the border region is greater than a length of the black matrix in each of the first display region and the second display region.

19. A spliced screen, comprising a plurality of the display panels according to claim 1, wherein the border regions of the plurality of display panels are spliced with each other.

20. A display apparatus, comprising the display panel according to claim 1.
